(19) United States
(12) Patent Application Publication
(10) Pub. No.: US 2002/0063318 A1
(43) Pub. Date: May 30, 2002

(54) Ball grid array (BGA) mounting device

(75) Inventors: Jay Robert Mitchell, Mesa, AZ (US); Richard John, Chandler, AZ (US); Naomi Lashmet, Scottsdale, AZ (US)

Correspondence Address: MOTOROLA, INC., CORPORATE LAW DEPARTMENT - #56-238, 3102 NORTH 56TH STREET, PHOENIX, AZ, 85018, US

(73) Assignee: Motorola, Inc.

(21) Appl. No.: 09/725,559

(22) Filed: Nov. 29, 2000

(51) Int. Cl. H01L 23/02

(52) U.S. Cl. 257/678

(57) ABSTRACT

An improved ball grid array assembly is disclosed. The assembly includes a ball grid array package (100), a substrate (104), and an insert device (108) interposed therebetween. Insert device (108) includes an array of contacts configured to couple to package (110) and an array of solder balls (112) configured to couple to a printed circuit board (116). Insert device (108) reduces stresses in the assembly caused by any mismatch of the thermal coefficients of expansion of BGA package (100) and printed circuit board (116).

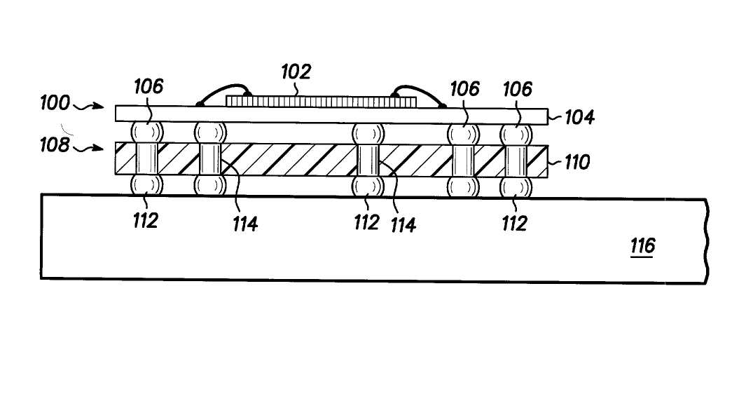

### TECHNICAL FIELD

The present invention relates, generally, to ball grid array (BGA) mounting techniques and, more particularly, to an interface device for use in mounting BGA assemblies to circuit boards.

### BACKGROUND ART AND TECHNICAL PROBLEMS

Ball grid array (BGA) packages are generally well known in the art. A typical BGA package includes a microelectronic device, for example, a die, mounted on top of a thin plane or substrate. On the opposite (bottom) side of the substrate is an array of solder balls, typically arranged as a square matrix of evenly spaced apart solder balls. When mounted to a printed circuit board, each solder ball in the grid provides an electrical connection between an electrical node within the microelectronic device of the BGA package and a corresponding electrical node on the circuit board. Accordingly, the printed circuit board upon which the BGA package is mounted typically has an array of contacts which matches the footprint of the ball grid array.

Presently known mounting techniques generally involve placing a BGA package on a printed circuit board surface, with the ball grid array in alignment with the corresponding array of contacts on the printed circuit board. The assembly is heated in a reflow oven to melt the solder balls to thereby ensure good mechanical and electrical connections between each ball in the BGA grid and the corresponding contact on the printed circuit board.

BGA packages are increasingly used in, for example, portable hand-held electronics because of their board area, high manufacturing yields, and thermal transfer efficiencies. However, BGA packages are somewhat disadvantageous as compared to leaded packages in high thermal cycle environments, such as aerospace.

A technique is thus needed which permits the use of BGA packages in environments which have wide temperature variations, high thermal cycles, or a combination of these factors.

### BRIEF DESCRIPTION OF THE DRAWING

The subject invention will hereinafter be described in conjunction with the appended drawing figure, wherein the referenced numerals in the drawing figure correspond to the associated descriptions provided below, and the drawing figure is a schematic view of a BGA package shown mounted to a printed circuit board in accordance with a preferred embodiment of the present invention.

### DETAILED DESCRIPTION OF THE DRAWING

In a preferred embodiment of the present invention, a BGA package 100 is schematically shown in the drawing figure mounted to a printed circuit board 116 in accordance with a preferred embodiment of the present invention. BGA package 100 includes a microelectronic structure (e.g., a die) 102 mounted to a top surface of a mounting substrate 104. A ball grid array 106 comprises a series of solder balls extending from the bottom surface of substrate 104. In a typical configuration, ball grid array 106 is configured as a square matrix of solder balls.

Printed circuit board 116, upon which BGA package 100 is mounted, typically includes an array of electrical contacts corresponding to the footprint of the ball grid array 106. Accordingly, when BGA package 100 is placed upon printed circuit board 116 in alignment with the foregoing array of contacts (not shown), the solder is reflowed to thereby ensure the mechanical and electrical integrity of the electrical connections. In this regard, it will be appreciated that the solder comprising each solder ball in ball grid array 106 tends to repel the surface of the printed circuit board 116, yet is attracted to the discrete electrical contacts in the array of contacts on the surface of printed circuit board 116. These two complementary phenomenon, namely, that solder attracts solder and the nonconductive surfaces of circuit board 116 and substrate 104 repel solder, produce a self-aligning effect during reflow which tends to compensate for minor misalignment between ball grid array 106 and the corresponding contact array on circuit board 116. In environments characterized by high-frequency thermal cycles, thermal swings having a high amplitude, or a combination of both, differences between the coefficient of thermal expansion (CTE) of substrate 104 and the CTE of circuit board 116 produce mechanical stress at the solder contacts. In particularly harsh thermal environments, thermal cycle fatigue can result in premature failure of the electrical contacts, which renders BGA packages ill suited for these environments.

In accordance with the preferred embodiment of the present invention, an interface device 108 is positioned between BGA package 100 and printed circuit board 116. Device 108 acts as a “thermal shock absorber” by reducing stress at substrate 104 and the contacts on the printed circuit board caused by any mismatch of the respective CTE.

In the illustrated embodiment, interface device 108 comprises an interface board 110, an interface array 112, and a plurality of electrical connectors 114. Interface array 112 is advantageously configured to match the footprint of ball grid array 106. Indeed, in a particularly preferred embodiment, interface array 112 may be similar to or even identical to the underside of BGA package 100 in terms of, for example, the size and material composition of the solder balls and the physical layout of the solder balls. In this way, interface device 108 may be interposed between BGA package 100 and circuit board 116 in a manner which does not require any redesign or reconfiguration of circuit board 116 or BGA package 100.

Interface device 108 may also include an array of contacts (not shown) on the upper surface of interface device 108; this array of contacts should be substantially similar to or identical to the array of contacts on the surface of printed circuit board 116 to which BGA package 100 would be mounted in the absence of interface device 108. Conductors 114 extend through interface board 110, connecting each contact on the top of interface device 108 with a corresponding one of the solder balls comprising interface array 112. In this way, the presence of interface device 108 does not compromise the electrical connection between BGA package 100 and printed circuit board 116.

In a preferred embodiment, interface board 110 is made from a compliant material, such as a polytetraflouroethylene (PTFE) composite, for example, Duroid™ available from the Rogers Corporation. In addition, interface board 110 also exhibits high electrical impedance to minimize cross-talk among the various electrical conductors 114.

The thickness of interface board 110 will influence the extent to which interface device 108 effectively distributes the stresses associated with thermal cycling. The present inventors have found that a 0.010 inch (″) thick interface board 110 yields acceptable cycle data, although thickness in the range of 0.005″ to 0.050″ may be used depending on, inter alia, the size of the electrical contact area, the mechanical properties of interface board 110 and the intended environment.

Although the present invention has been described with reference to the drawing figure, those skilled in the art will appreciate that the scope of the invention is not limited to the specific forms shown in the figure. Various modifications, substitutions, and enhancements may be made to the descriptions set forth herein, without departing from the spirit and scope of the invention which is set forth in the appended claims.

What is claimed is:

1. A ball grid array (BGA) assembly configured for attachment to a circuit board, the circuit board having a plurality of circuit board electrical contacts arranged in a predetermined pattern, the BGA assembly comprising:
a BGA package, including a microelectronic device mounted on a substrate and an array of BGA solder balls extending from said substrate, said array of BGA solder balls being configured in accordance with said predetermined pattern; and
an insert device, including:
an interface board having a top side and a bottom side;
a plurality of insert device contacts on said top side configured to contact said array of BGA solder balls; and
an array of insert device solder balls configured to contact said plurality of circuit board electrical contacts.

2. The BGA assembly of claim 1, wherein said interface board comprises a resiliently deformable, electrically insulative material having a plurality of electrical conductors extending therethrough.

3. The BGA assembly of claim 1, wherein said predetermined pattern comprises a rectangular, two dimensional matrix.

4. The BGA assembly of claim 1, wherein said interface board comprises a polytetraflouroethylene composite in a range of about 0.005 inches to 0.050 inches in thickness.

5. The BGA assembly of claim 4, wherein said array of insert device solder balls are arranged in accordance with said predetermined pattern.
